(19) United States
(12) Patent Application Publication
(10) Pub. No.: US 2025/0231456 A1
(43) Pub. Date: Jul. 17, 2025

(54) METAL OXIDE WET ETCHING METHOD

(71) Applicant: PSIQUANTUM CORP., Palo Alto, CA (US)

(72) Inventors: Colleen Shang FENRICH, Mountain View, CA (US); George KOVALL, Campbell, CA (US)

(21) Appl. No.: 18/697,692

(22) PCT Filed: Oct. 3, 2022
(86) PCT No.: PCT/US2022/045513

§ 371 Date: Apr. 1, 2024

Related U.S. Application Data
(60) Provisional application No. 63/251,139, filed on Oct. 1, 2021.

(51) Int. Cl. G02F 1/21; G02F 1/225

(52) U.S. Cl. CPC G02F 1/212; G02F 1/225

(57) ABSTRACT

An etching method includes forming a metal oxide layer comprising a barium titanate layer or a strontium titanate layer over a substrate, forming a patterned masking layer over the metal oxide layer, and etching the metal oxide layer using a wet etching medium containing hydrofluoric acid, one or more additional acids having an acid dissociation constant greater than that of the hydrofluoric acid, and a diluent.

### FIELD

Embodiments herein relate generally to methods for etching metal oxide layers, for example to generate components of electro-optic devices, such as phase shifters and switches.

### BACKGROUND

Electro-optic (EO) modulators and optical switches are useful components for the control and manipulation of optical signals. Some EO modulators utilize free-carrier electro-refraction, free-carrier electro-absorption, the Pockel's effect, or the DC Kerr effect to modify optical properties during operation, for example, to change a phase of light propagating through the EO modulator or switch. Optical phase modulators may be used in integrated optics systems, waveguide structures, integrated optoelectronics, etc.

Despite the progress made in the field of EO modulators and switches, there is an ongoing need for improved methods and systems related to patterning and etching wafer stacks for use in EO modulators, switches, and related devices.

### SUMMARY

An embodiment etching method includes forming a metal oxide layer comprising a barium titanate layer or a strontium titanate layer over a substrate, forming a patterned masking layer over the metal oxide layer, and etching the metal oxide layer using a wet etching medium containing hydrofluoric acid, one or more additional acids having an acid dissociation constant greater than that of the hydrofluoric acid, and a diluent.

### BRIEF DESCRIPTION OF THE DRAWINGS

The accompanying drawings, which are incorporated herein and constitute part of this specification, illustrate example embodiments of the disclosure, and together with the general description given above and the detailed description given below, serve to explain the features of the disclosure.

FIG. 1 is a simplified schematic diagram illustrating an optical switch, according to various embodiments.

FIG. 2 is a schematic diagram of a pre-fabricated wafer including stacked layers, according to various embodiments.

FIG. 3A is a simplified schematic diagram illustrating a cross section of a waveguide structure that shows the direction of an induced electric field, according to various embodiments.

FIG. 3B is a simplified schematic diagram illustrating a cross section of a waveguide structure, according to various embodiments.

FIG. 4 is a simplified schematic diagram showing a top view of a waveguide structure, according to various embodiments.

FIG. 5 is a schematic diagram of a wafer etching apparatus, according to various embodiments.

FIG. 6 is a schematic illustration of an ion milling etch procedure.

FIG. 7 is a schematic illustration of using ionized partial gas mixture to etch an electro-optic layer, according to various embodiments.

FIG. 8 is a schematic illustration of a thin SiO₂ hard mask that may be used to etch a wafer, according to various embodiments.

FIG. 9 is a schematic illustration of a thin Si₃N₄ hard mask that may be used to etch a wafer, according to various embodiments.

FIG. 10 is a schematic illustration of a thick SiO₂ hard mask that may be used to etch a wafer, according to various embodiments.

FIG. 11 is a schematic illustration of a thick Si₃N₄ hard mask that may be used to etch a wafer, according to various embodiments.

FIG. 12A is a vertical cross-sectional view of an intermediate structure that may be used in the formation of an optical component, according to various embodiments.

FIG. 12B is a vertical cross-sectional view of a further intermediate structure that may be used in the formation of an optical component, according to various embodiments.

FIG. 13A is a vertical cross-sectional view of an optical component, according to various embodiments.

FIG. 13B is a vertical cross-sectional view of a further optical component, according to various embodiments.

### DETAILED DESCRIPTION

The various embodiments are described in detail with reference to the accompanying drawings. The drawings are not necessarily to scale, and are intended to illustrate various features of the disclosure. Wherever possible, the same reference numbers will be used throughout the drawings to refer to the same or like parts. References made to particular examples and implementations are for illustrative purposes, and are not intended to limit the scope of the disclosure or the claims.

It will also be understood that, although the terms first, second, etc. are, in some instances, used herein to describe various elements, these elements should not be limited by these terms. These terms are used only to distinguish one element from another. For example, a first electrode layer could be termed a second electrode layer, and, similarly, a second electrode layer could be termed a first electrode layer, without departing from the scope of the various described embodiments. The first electrode layer and the second electrode layer are both electrode layers, but they are not the same electrode layer.

Disclosed embodiments relate etching and patterning methods for constructing components of optical systems. Example embodiments are provided in the context of integrated optical systems that include active optical devices, but the disclosure is not limited to such examples and has wide applicability to a variety of optical and optoelectronic systems.

According to some embodiments, the active photonic devices described herein utilize electro-optic effects, such as free carrier induced refractive index variation in semiconductors, the Pockels effect, and/or the DC Kerr effect to implement modulation and/or switching of optical signals. Thus, embodiments are applicable to both modulators, in which the transmitted light is modulated either ON or OFF, or light is modulated with a partial change in transmission percentage, as well as optical switches, in which the transmitted light is output on a first output (e.g., waveguide) or a second output (e.g., waveguide) or an optical switch with more than two outputs, as well as more than one input. Thus, embodiments of this disclosure are applicable to a variety of system configurations including an M(input)×N(output) systems that utilize the methods, devices, and techniques discussed herein. Some embodiments also relate to electro-optic phase shifter devices, also referred to herein as phase adjustment sections, which may be employed within switches or modulators.

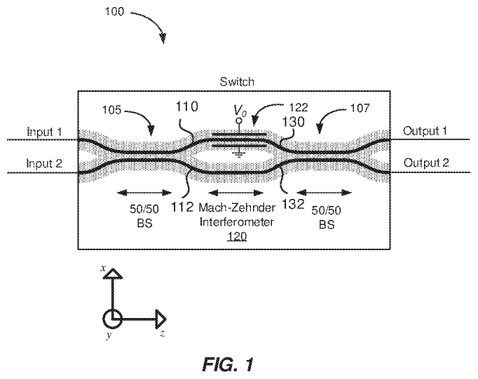

FIG. 1 is a simplified schematic diagram illustrating an optical switch, according to various embodiments. Referring to FIG. 1, switch 100 includes two inputs: Input 1 and Input 2 as well as two outputs: Output 1 and Output 2. As an example, the inputs and outputs of switch 100 may be implemented as optical waveguides configured to support single mode or multimode optical beams. As an example, switch 100 may be implemented as a Mach-Zehnder interferometer coupled with a set of 50/50 beam splitters 105 and 107, respectively. As illustrated in FIG. 1, Input 1 and Input 2 are optically coupled to a first 50/50 beam splitter 105, also referred to as a directional coupler, which receives light from the Input 1 or Input 2 and, through evanescent coupling in the 50/50 beam splitter, directs 50% of the input light from Input 1 into waveguide 110 and 50% of the input light from Input 1 into waveguide 112. Concurrently, first 50/50 beam splitter 105 directs 50% of the input light from Input 2 into waveguide 110 and 50% of the input light from Input 2 into waveguide 112. Considering only input light from Input 1, the input light is split evenly between waveguides 110 and 112.

Mach-Zehnder interferometer 120 includes phase adjustment section 122. Voltage V₀ may be applied across the waveguide in phase adjustment section 122 such that it may have an index of refraction in phase adjustment section 122 that is controllably varied. Because light in waveguides 110 and 112 may still have a well-defined phase relationship (e.g., they may be in-phase, 180° out-of-phase, etc.) after propagation through the first 50/50 beam splitter 105, phase adjustment in phase adjustment section 122 may introduce a predetermined phase difference between the light propagating in waveguides 130 and 132. The phase relationship between the light propagating in waveguides 130 and 132 may cause output light to be present at Output 1 (e.g., light beams are in-phase) or Output 2 (e.g., light beams are out of phase), thereby providing switch functionality as light is directed to Output 1 or Output 2 as a function of the voltage V₀ applied at the phase adjustments section 122. Although a single active arm is illustrated in FIG. 1, in other embodiments both arms of the Mach-Zehnder interferometer may include phase adjustment sections.

As illustrated in FIG. 1, electro-optic switch technologies, in comparison to all-optical switch technologies, use an applied electrical bias (e.g., V₀ in FIG. 1) across the active region of the switch to produce optical variation. The electric field and/or current that is induced by application of this voltage bias causes changes in one or more optical properties of the active region, such as the index of refraction or absorbance. Although a Mach-Zehnder interferometer implementation is illustrated in FIG. 1, the disclosure is not limited to this particular switch architecture and other phase adjustment devices are included within the scope of this disclosure, including ring resonator designs, Mach-Zehnder modulators, generalized Mach-Zehnder modulators, and the like.

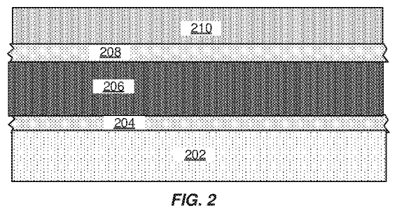

The optical switch illustrated in FIG. 1 may include a waveguide structure that has been patterned from a wafer. FIG. 2 illustrates an example wafer that may be received from a wafer manufacturer and etched according to embodiments described herein, to produce the waveguide structure. FIG. 2 illustrates a cross section of a first wafer including a layer stack that may be received as part of a fabrication process for various devices described herein, according to various embodiments. As illustrated, a first insulating substrate layer 202 may be (optionally) disposed beneath a seed layer 204, which is disposed beneath an electro-optic layer 206, which is (optionally) disposed beneath an electrode layer 208, which is (optionally) disposed beneath a second insulating substrate layer 210. Alternatively, the electrode layer 208 may be located between the electro-optic layer 206 and the first insulating substrate layer 202. While FIG. 2 illustrates that each of the five layers 202 to 210 are present, any one or more of these layers may be absent, in various embodiments. In other words, the first wafer may be of various types depending on the specific fabrication method to be employed, and the seed layer, electrode layer, and second substrate layer may be optionally present or not present, as desired. One or more of the layers illustrated in FIG. 2 may be chemically etched to produce an electro-optical component, according to embodiments described herein.

Each of the layers of the wafer may be of any of a variety of types of materials. For example, the electrode layer 208 may include a conducting material such as a metal, or alternatively they may be composed of a semiconductor material. In various embodiments, the electrode layer may include one of gallium arsenide (GaAs), an aluminum gallium arsenide (AlGaAs)/GaAs heterostructure, an indium gallium arsenide (InGaAs)/GaAs heterostructure, zinc oxide (ZnO), zinc sulfide (ZnS), indium oxide (InO), doped silicon, strontium titanate (STO), doped STO, barium titanate (BTO), barium strontium titanate (BST), hafnium oxide, lithium niobite, zirconium oxide, titanium oxide, graphene oxide, tantalum oxide, lead zirconium titanate (PZT), lead lanthanum zirconium titanate (PLZT), strontium barium niobate (SBN), aluminum oxide, aluminum oxide, doped variants or solid solutions thereof, or a two-dimensional electron gas. For embodiments where the electrode layer may include doped STO, the STO may be either niobium doped or lanthanum doped, or include vacancies, according to various embodiments.

In various embodiments, the electro-optic layer 206 may include one or more of STO, BTO, BST, hafnium oxide, lithium niobite, zirconium oxide, titanium oxide, graphene oxide, tantalum oxide, PZT, PLZT, SBN, aluminum oxide, aluminum oxide, or doped variants or solid solutions thereof. The electro-optic layer may be composed of a transparent material having an index of refraction that is larger than an index of refraction of the first and second insulating substrate layers, in some embodiments.

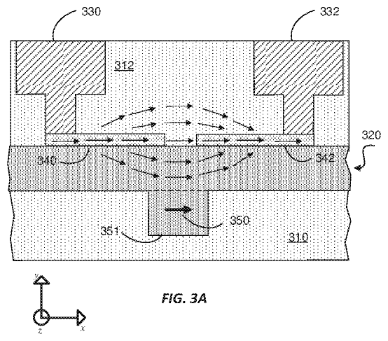

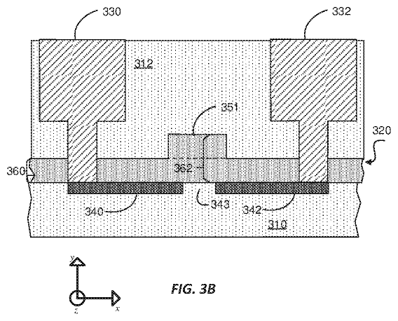

FIG. 3A is a simplified schematic diagram illustrating a cross section of an example completed waveguide structure, where the direction of the induced electric field is illustrated with arrows, according to some embodiments. The waveguide structure illustrated in FIG. 3A may be fabricated from the wafer illustrated in FIG. 2 by performing etching techniques of embodiments described herein. FIG. 3A exhibits two electrical contacts, and each electrical contact includes a lead (330 and 332) connected to an electrode (340 and 342). It is noted that, as used herein, the term “electrode” refers to a device component that directly couples to the waveguide structure (e.g., to alter the voltage drop across the waveguide structure and actuate a photonic switch). Further, the term “lead” may refer to a backend structure that couples the electrodes to other components of the device (e.g., the leads may couple the electrodes to a controllable voltage source), but the leads are isolated from and do not directly couple to the waveguide structure. In some embodiments, the leads may be composed of a metal (e.g., copper, gold, etc.), or alternatively, a semiconductor material.

As illustrated, FIG. 3A illustrates a photonic device including first and second cladding layers, 310 and 312, on either side of the waveguide. It is noted that the terms “first” and “second” are meant simply to distinguish between the two cladding layers, and, for example, the term “first cladding layer” may refer to the cladding layer on either side of the waveguide.

FIG. 3A further illustrates a slab layer 320 including a first material that is coupled to the first electrode of the first electrical contact and the second electrode of the second electrical contact. In some embodiments, the waveguide structure further includes a ridge portion 351 composed of the first material (or a different material) and coupled to the slab layer, where the ridge portion is disposed between the first electrical contact and the second electrical contact.

As illustrated in FIG. 3A, the small arrows show the induced electric field direction which generally points along the positive x-direction through the electrodes of the device.

The electric field curves in a convex manner both above and below the electrodes, as illustrated. Furthermore, the large arrow 350 pointing in the positive x-direction illustrates the direction of polarization of an optical mode that may travel through the slab layer and the waveguide.

FIG. 3B illustrates an architecture where the ridge portion of the waveguide structure 351 is disposed on the top side of the slab layer and extends into a first cladding layer 312, the first electrode and the second electrode are coupled to the slab layer on the bottom side of the slab layer opposite the top side. As illustrated, the combination of the ridge portion and the slab layer has a first thickness 362 greater than a second thickness 360 of the slab layer alone 320, and the excess of the first thickness relative to the second thickness extends into the first cladding layer 312 on the top side of the slab layer 320. As illustrated in FIG. 3B, the first electrode 340 and the second electrode 342 may be coupled to the slab layer 320 on the bottom side of the slab layer opposite the top side. Further, the first electrical contact 330 may be coupled to the first electrode 340 by penetrating through the slab layer 320 from the top side of the slab layer to the bottom side of the slab layer, and the second electrical contact 332 may be coupled to the second electrode 342 by penetrating through the slab layer 320 from the top side of the slab layer to the bottom side of the slab layer.

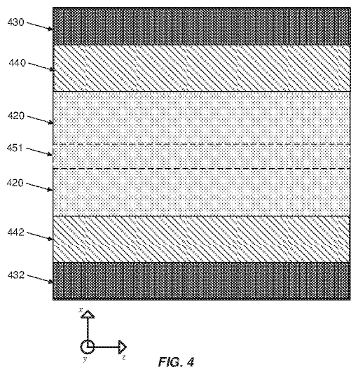

FIG. 4 is a top-down view of a photonic phase-shifter architecture of FIGS. 3A and 3B, which may be patterned according to embodiments described herein. As illustrated, the phase-shifter may include first 430 and second 432 leads, first 440 and second 442 electrodes, a slab (e.g., waveguide) layer 420, and a ridge portion of the waveguide structure 451.

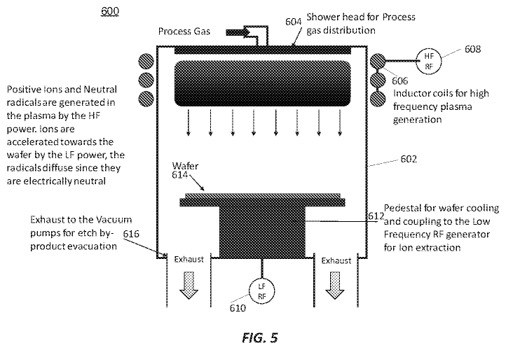

FIG. 5 is a schematic diagram illustrating a wafer etching apparatus 600, according to some embodiments. The illustrated wafer etching apparatus is one example of a wafer etching apparatus. Various other types of apparatus may be used in other embodiments to perform the etching processes described herein. As illustrated, a process gas (e.g., a combination of HBr and Cl₂, among other possibilities) may be inserted through the top of the etching process chamber 602, and distributed over the top region of the chamber using a shower head 604. As illustrated, inductor coils 606 wrapped around the chamber 602 are connected to a high frequency (HF) radio frequency (RF) generator (e.g., a 60 MHz RF generator) 608 which is configured to introduce a rapidly oscillating magnetic field within the chamber 602.

The induced oscillating field may interact with the process gas to ionize the gas. At the bottom of the chamber 602, a low frequency (LF) RF generator (e.g., typically a 13.5 MHz generator, or another frequency) 610 may be capacitively coupled to the pedestal 612 to introduce an oscillating capacitive charge on the top surface of the pedestal. This LF oscillating charge will accelerate ionized gas particles downward to collide with and chemically etch the wafer (e.g., the substrate containing one or more layers to be etched) 614 positioned on the pedestal 612. Finally, gaseous chemical by-products of the chemical etching reaction may be exhausted through a low-strength pump 616 at the bottom of the chamber 602.

Constructing the components of the electro-optical systems described above may involve an etching process to modify a wafer into an electro-optical component, such as a waveguide structure. Conventional methods for wafer etching exhibit limitations, and embodiments herein present improved methods for wafer etching.

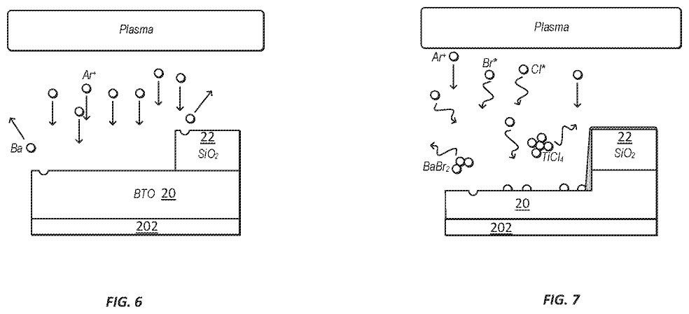

FIG. 6 illustrates an ion milling method for etching BTO (i.e., BaTiO₃). BTO is a difficult material to pattern using reactive ion etch (RIE), because BTO does not form volatile by-products with fluorine or chlorine, the halides commonly used in plasma etching. The chemical by-products of etching BTO using conventional fluorine and chlorine are non-volatile below approximately 1500° C. Accordingly, these by-products may not desorb from the wafer at the temperatures and pressures available in an RIE chamber. As a consequence, as illustrated in FIG. 6, some previous implementations for patterning a BTO layer 20 have been focused on ion-beam etching using argon, a process that is slow and has little selectivity to the mask (e.g., a silicon oxide hard mask) 22. During ion milling, argon ions are accelerated towards the BTO surface and physically break off barium and titanium atoms. These atoms are then pumped out through the exhaust. However, the etched atoms may often redeposit elsewhere on the surface of the wafer, causing undesirable defects. In addition, ion milling is non-selective so that effectively utilizing a hard mask may require the hard mask 22 to be thicker than the desired patterning depth, leading to increased material costs and etching time.

To address these and other concerns, embodiments herein provide a method where the BTO layer 20 is etched using a mixture of hydrogen bromide (HBr) and chlorine (Cl₂) to form the volatile by-products BaBr₂ and TiCl₄, respectively. As illustrated in FIG. 7, a partial gas mixture of HBr and Cl₂ is ionized, and this ionized gas is used to etch BTO. BaBr₂becomes volatile at 120° C. at 1 atm pressure which is well within reach of conventional RIE chambers. In various embodiments, in order to pattern the wafer, several integration schemes with SiO₂ or Si₃N₄ hard masks 22, 24 may be used, as both materials are compatible with HBr/Cl₂ containing chemistries.

In some embodiments, formation of BaBr₂ may be assisted by the presence of oxygen, hydrogen, and/or argon ions in the plasma. The oxygen, hydrogen, and/or argon ions may be accelerated towards the surface at lower energy compared to that used for ion milling. The Br and Cl radicals are electrically neutral and may diffuse to the wafer surface. Both by-products readily desorb from the wafer surface and may be pumped out of the chamber without redepositing on the wafer.

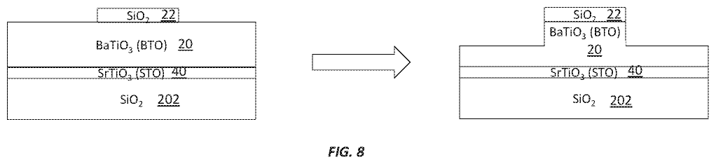

Additional benefits are that the HBr/Cl₂ mixture is selective to SiO₂ or Si₃N₄ hard masks. The etch rate of BTO is also higher using a chemically assisted etch compared to a physical ion milling process and it has a lower risk of striations resulting in line edge roughness. FIGS. 8-11 illustrate different methods for utilizing a hard mask when patterning an electro-optic layer, according to various embodiments.

FIG. 8 illustrates utilization of a hard mask 22 of SiO₂ to pattern the BTO layer 20. In one embodiment, the BTO layer 20 may be used as the slab/ridge electro-optic layer 320 in the device of FIG. 3B. The SiO₂ hard mask 22 is selected because this material exhibits high selectivity to SiO₂ in HBr-based plasmas. The hard mask 22 may be patterned in a previous step. Optionally, an STO layer 40 may be located below the BTO layer 20. The STO layer 40 may be used to form the dielectric electrodes 340, 342 of FIG. 3B. The STO layer 40 may be patterned prior to forming the BTO layer 20 by any suitable method, such as ion milling. The optional STO layer 40 and the BTO layer 20 may be formed over the insulating substrate layer 202, such as a silicon dioxide or silicon nitride layer described above with respect to FIG. 2.

The insulating substrate layer 202 may be a temporary layer which is subsequently removed or may be a retained in the final electro-optic device as a cladding layer. Furthermore, the seed layer 204 may optionally also be formed below the BTO layer 20 as described above. The seed layer 204 may subsequently be removed or retained in the final electro-optic device. As illustrated, the BTO layer 20 is etched using the HBr/Cl₂ chemistry. In addition to the two main etching gases, O₂ is added for selectivity to the SiO₂ hard mask 22 as well as for profile control and argon is added to supply energy in the form of ion bombardment.

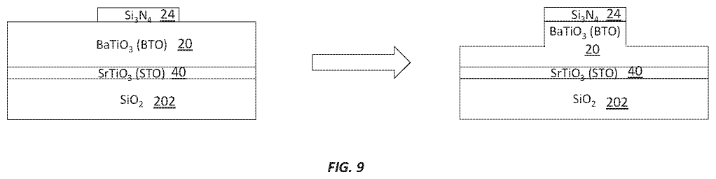

FIG. 9 illustrates utilizing a hard mask of silicon nitride (Si₃N₄) 24 to pattern the BTO layer 20. Silicon nitride is similar to silicon dioxide in that it is difficult to etch with HBr which causes high selectivity similar to the use of a SiO₂ hard mask 22, the BTO layer 20 is etched using HBr/Cl₂ chemistry. In addition to the two main etching gases, O₂ is added for profile control and argon is added to supply energy in the form of ion bombardment just as in the example of using a SiO₂ hard mask.

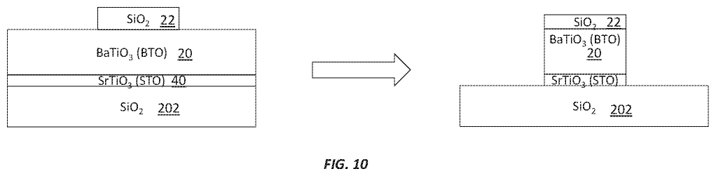

FIG. 10 illustrates a similar hard mask of SiO₂ 22 as shown in FIG. 8, which may be used to pattern the BTO layer 20 in some embodiments. The hard mask 22 is thicker than in FIG. 8 due to the increased etch depth. The BTO layer 20 and the STO layer 40 are etched together using the HBr/Cl₂ chemistry or by optionally using ion milling to etch the STO layer 40 after the BTO layer 20 is etched using the HBr/Cl₂ chemistry. In addition to the two main etching gases, O₂ is added for selectivity to the SiO₂ hard mask 22 as well as for profile control and argon is added to supply energy in the form of ion bombardment. In this embodiment, the full BTO stack is etched and the process stops on the SiO₂ insulating substrate layer 202 underneath.

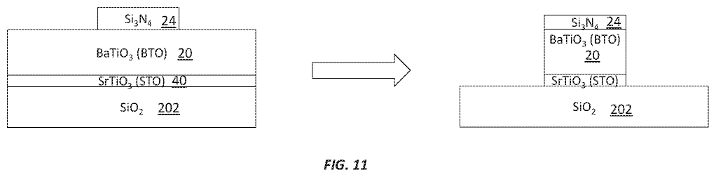

FIG. 11 illustrates a hard mask of Si₃N₄ 24, similar to that shown in FIG. 9, which may be used to pattern the BTO layer 20. The hard mask 24 is thicker than that shown in FIG. 9 to accommodate the increased etch depth. The BTO layer 20 and the STO layer 40 are etched together using the HBr/Cl₂ chemistry or by optionally using ion milling to etch the STO layer 40 after the BTO layer 20 is etched using the HBr/Cl₂ chemistry. In addition to the two main etching gases, O₂ is added for selectivity to the silicon nitride hard mask 22 as well as for profile control and argon is added to supply energy in the form of ion bombardment. In this embodiment, the full BTO stack is etched and the process stops on the SiO₂ insulating substrate layer 202 underneath.

Embodiments described herein for BTO layer 20 etching provide advantages over existing methods, such as ion milling using argon ions mixed with fluorine. Since the by-products produced by embodiments herein readily desorb from the surface, the produced wafer (i.e., the insulating substrate layer 202 supporting the etched BTO layer 20) may exit the process chamber 602 shown in FIG. 5 with fewer defects compared to wafers produced with ion milling processes. Additionally, chemically assisted etching has a higher etch rate, resulting in shorter processing times. Further, etching methods described according to some embodiments may have more tunable parameters such as pressure, power and gas composition that allows for improved control of the process. Embodiments herein offer improved selectivity to the hard mask, simplifying process integration. Chemical etching methods described herein are less physical than ion milling, reducing the risk of striations and edge channeling that in turn causes line edge roughness.

In some embodiments, HBr may react with moisture from the air and redeposit on the wafer. This re-deposition is referred to as time-dependent haze and may be dissolved during wafer cleaning. In some embodiments, non-processed wafers may be physically separated from processed wafers. This may prevent the haze from depositing on the surface of unprocessed wafers and causing micro-masking.

As described above, BTO and STO thin film patterning using plasma dry etching has a slow etch rate and the Ba and/or Sr containing residue may not be effectively removed since these materials are not easily volatilized due to high temperatures required for volatilizing Ba and Sr based etch products. For example, BaF₂ may only be volatilized for temperatures above 2260° C., BaCl₂ may only be volatilized for temperatures above 1560° C., SrF₂ may only be volatilized for temperatures above 2460° C., SrCl₂ may only be volatilized for temperatures above 1250° C., etc. As a result, the Ba and/or Sr containing residue may need to be removed from the etched surface by sputtering. Under such sputtering conditions, however, the mask material would most likely also be sputtered. Thus, the etching process would have a low etch selectivity to the mask material.

Another consequence of the high volatilization temperatures of halogenated Ba and/or Sr compounds is that the etch process tends to preferentially etch Ti from BTO or STO, leading to a deviation from the 1:1 Ba:Ti (Sr:Ti) stoichiometry of the material. Such a deviation in the stoichiometry of the material may have an impact on material properties and device performance. Ion beam etching or ion milling (micromachining) is an alternative to plasma dry etching but has very slow etch rate, poor selectivity to mask materials, and may not available for use with 300 mm wafer fabrication. BTO and STO patterning using uncatalyzed wet etch chemistries may also suffer from slow etch rates.

Disclosed embodiments provide a catalyzed wet etching method to etch BTO and/or STO thin films in which the etchant (i.e., etching medium) chemistry is specifically tuned to achieve a rapid etch rate unattainable in plasma dry etching or uncatalyzed wet etching. The embodiment methods generate Ba and/or Sr containing residue (e.g., etch products as a result of chemical reaction) that may be solubilized in an aqueous solution. As such, the embodiment catalyzed wet etching methods etch BTO and STO thin films with high selectivity to a photoresist mask material and effectively remove the Ba and/or Sr containing residue.

BTO and/or STO thin film (i.e., layer) patterning may be performed using a masking layer. A photoresist may be used as a masking layer in some embodiments, while other suitable masking materials (e.g., hard masks, such as silicon oxide, silicon nitride, metal, carbon, etc.) may be used in other embodiments. Portions of the BTO or STO film not covered by the masking layer may be subject to chemical reaction to remove the BTO film. In one embodiment, unmasked portions of the BTO or STO film may be completely or partially etched using a catalyzed wet etch process that relies on a chemical reaction to remove the desired material without leaving significant residue byproducts of the film or the process.

An embodiment of catalyzed wet etch chemistry includes an etching medium containing a diluent, an aqueous source of fluorine, such as hydrofluoric acid (HF), and at least one additional acid having an acid dissociation constant (e.g., first dissociation constant Kₐ₁) greater than that of HF, which catalyzes the wet etch. The etching medium may also optionally include an optional buffer, an optional oxidizing agent, and/or one or more optional additives (e.g., a surfactant, a solvent, such as ethanol, etc.). A ratio among solution constituents may be varied and a concentration of solution constituents may be controlled by an amount of diluent used in the formulation. The disclosed wet chemical etching process may be performed at room temperature conditions. However, in other embodiments, the wet chemical etching process may be carried out under other conditions.

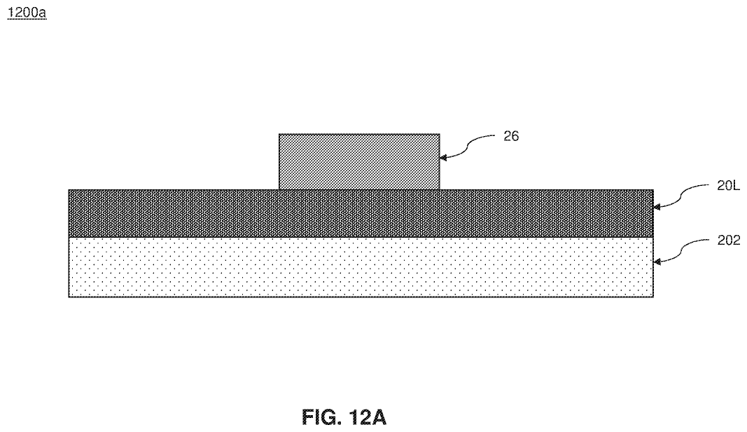

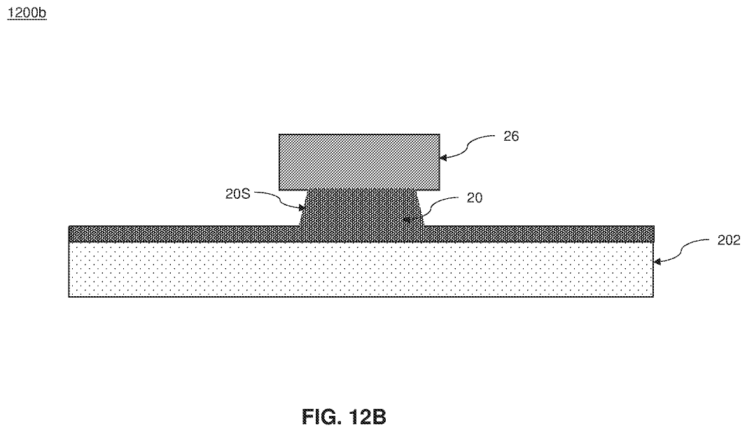

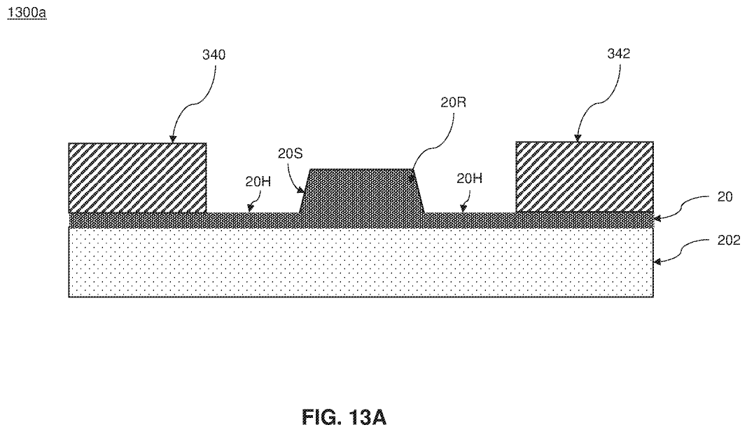

FIG. 12A is a vertical cross-sectional view of an intermediate structure 1200a that may be used in the formation of an optical component, according to various embodiments. The intermediate structure 1200a may include an electro-optic layer 20L formed over a substrate 202. The electro-optic layer 20L may be deposited as a blanket (i.e., un-patterned) layer and may include an electro-optic material, such as BTO or STO, as described above. The intermediate structure 1200a may further include a patterned masking layer, such as a photoresist masking layer 26. Alternatively, SiO₂ or Si₃N₄ hard masks 22, 24 described above may be used as a masking layer. The patterned photoresist 26 may be formed by depositing a blanket layer (not shown) of photoresist material and patterning the photoresist material using photolithography techniques to form the patterned photoresist 26. The patterned photoresist 26 may then be used as a mask layer to selectively etch the electro-optic layer 20L.

An etch process may include introducing the wet etchant medium in a liquid state that may interact with the electro-optic layer 20L to thereby etch the electro-optic layer 20L and to generate various etch products that may be removed from the surface of the electro-optic layer 20L. As described above, and in further detail below, the etchant medium may be provided in the form of a wet etch solution.

FIG. 12B is a vertical cross-sectional view of an intermediate structure 1200b that may be used in the formation of an optical component, according to various embodiments. The wet etching generates Ba and/or Sr containing residue (e.g., etch products generated as a result of chemical reaction) 1208 that may be solubilized in an aqueous solution and thereby removed when the wet etching solution is removed from the structure 1200b, as schematically shown by the arrows.

As shown in FIG. 12B, the wet etch process may be stopped before etching through the entire thickness of the unmasked portions of the electro-optic layer 20 and before reaching the surface of the substrate 202. As mentioned above, the wet etch is an isotropic etch, in contrast to a dry etch which is an anisotropic etch. Thus, as shown in FIG. 12B, the wet etch may remove portions of the etched electro-optic layer 20 under the patterned photoresist 26, thereby generating undercut regions with tapered sidewalls 20S.

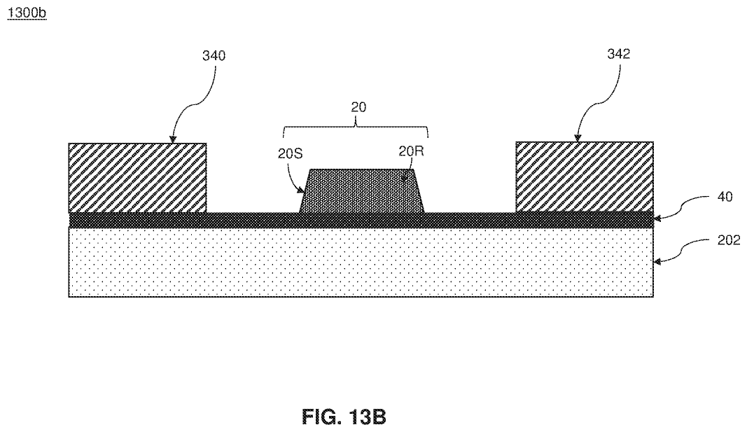

FIG. 13A is a vertical cross-sectional view of an optical component 1300a, according to an embodiment. The optical component 1300a may be formed using processes described above with reference to FIGS. 12A and 12B. In this regard, a wet etch process may be performed on the intermediate structure 1200a to isotropically etch portions of the etched electro-optic layer 20 under the patterned photoresist 26. The etched electro-optic layer 20 of FIG. 13A may include a ridge portion 20R having tapered sidewalls 20S and horizontal layer portions 20H located on each side of the ridge portion 20R over the substrate 202. At least the ridge portion 20R may serve as a waveguide in the optical component 1300a. The electro-optic component 1300a may then be formed by removing the patterned photoresist 26 (e.g., with a chemical solvent or by ashing) and by forming a first electrode 340 and a second electrode 342 on the horizontal portions 20H of the etched electro-optic layer 20.

FIG. 13B is a vertical cross-sectional view of a further optical component 1300b, according to an alternative embodiment. In this embodiment, the electro-optic layer 20 includes the BTO layer, and an additional STO layer 40 is formed between the substrate 202 and the BTO layer. In this embodiment, the wet etch may etch through the entire thickness of the unmasked portions of the electro-optic layer 20 (e.g., BTO layer) and reach a surface of the underlying STO layer 40. The etched electro-optic layer 20 includes just the ridge portion 20R having the tapered sidewalls 20S located on the underlying STO layer 40. Portions of the STO layer 40 may function as the dielectric electrodes, or additional electrodes 340, 342 may be formed on the STO layer 40 as shown in FIG. 13B.

The embodiment wet etching process may include variations of the HF concentrations and dilutions, and may include buffered HF solutions, such as buffered hydrofluoric acid, etc. Aqueous sources of F species other than HF may also be used instead of or in addition to HF. A variety of other acids having Ka1 greater than that of HF, may be used in conjunction with the HF solution (e.g., aqueous HF solution). Such other acids may include hydrochloric acid, sulfuric acid, phosphoric acid, hydroiodic acid, perchloric acid, hydrobromic acid, nitric acid, or organic acids, such as citric acid, oxalic acid, acetic acid, etc. These high Kₐ₁ acids catalyze the HF etching. An oxidizing agent, such as hydrogen peroxide (H₂O₂) may optionally be added.

The wet etching medium may include an organic or aqueous solvent and/or diluent. For example, water may be used as a solvent and/or diluent in the solution. Alternatively, an organic solvent, such as ethanol, may be combined with an aqueous HF solution. The above-described wet chemical etching medium may be applied as a blended solution. Alternatively, the various chemical components may be applied sequentially (e.g., a HF solution may be provided into a solvent and/or diluent first, followed by providing the high Kₐ₁ acid into the solution).

The wet etching medium may be applied to the intermediate structure 1200a in various ways. For example, an HF/acid solution may be provided as an etching bath and the intermediate structure 1200a is then dipped into the etching bath. In this embodiment, the step of etching the metal oxide layer comprises placing the substrate 202 containing the metal oxide layer 20 and the patterned masking layer 26 into a bath comprising the wet etching medium.

Alternatively, the wet etching medium may be applied to the intermediate structure 1200a using a spray tool to apply a mist of the chemical solution. In this embodiment, the step of etching the metal oxide layer comprises spraying the wet etch medium on exposed portions of the metal oxide layer 20 and on the patterned masking layer 26.

In further embodiments, the wet etching medium may be applied as a vapor using a vapor HF system or by placing the intermediate structure 1200a to be etched face down above a wet etching bath and allowing vapors from the bath to interact with the structure 1200a to thereby act as an etchant. In this embodiment, the step of etching the metal oxide layer comprises providing a vapor from the wet etching medium onto exposed portions of the metal oxide layer 20 and on the patterned masking layer 26.

Embodiment wet chemical etching processes have a higher etch rate than in typical plasma dry etching or uncatalyzed wet etching. For example, in a pure aqueous HF etch, the reaction between BTO and the etchant is governed by the following reaction that has a first etching reaction rate:

BaTiO₃₍ₛ₎+6HF(aq)↔BaF₂(s)+TiF₄₍ₛ₎+3H₂O(aq) (I)

When the high Kₐ₁ acid is added to the etching medium, according to various embodiments, it generates hydronium ions which causes an increase in formation of HF molecules from fluorine ions in the solution according to reaction (II):

H₃O⁺+F⁻↔HF+H₂O (II)

According to Le Chatelier's principle, the increase in HF molecule formation will push the equilibrium of reaction (I) forward, with a corresponding increased second etching reaction rate. Adding the high Kₐ₁ acid, such as nitric acid, for example, into the aqueous solution causes its dissociation according to reaction (III):

HNO_{3(aq)}→H_{(aq)}⁺+NO_{3(aq)}⁻ (III)

The proton (H⁺) created in this reaction (III) combines with water molecules to form the hydronium ion (H₃O⁺) according to reaction (IV):

H⁺+H₂O=H₃O⁺ (IV)

The hydronium ion (H₃O⁺) then interacts with the F⁻ as shown above in reaction (II) to generate additional HF, which catalyzes the reaction (I) forward and increases the etch rate. Similar reactions may occur with other high Kₐ₁ acids according to the following reactions:

Hl_{(g)}+H₂O_{(aq)}→H_{(aq)}⁺+l_{(aq)}⁻

HClO_{4(aq)}→H_{(aq)}⁺+ClO_{4(aq)}⁻

HBr_{(aq)}→H_{(aq)}⁺+Br_{(aq)}⁻

HCl_{(aq)}→H_{(aq)}⁺+Cl_{(aq)}⁻

H₂SO_{4(aq)}→H_{(aq)}⁺+HSO_{4(aq)}⁻

HNO_{3(aq)}→H_{(aq)}⁺+NO_{3(aq)}⁻

H₃PO_{4(aq)}→H_{(aq)}⁺+H₂PO_{4(aq)}⁻

For polyprotic acids considered above, such as phosphoric acid, multiple dissociations may occur, for example, according to the following reactions:

H₃PO_{4(aq)}→H_{(aq)}⁺+H₂PO_{4(aq)}⁻

H₂PO_{4(aq)}⁻→H_{(aq)}⁺+HPO_{4(aq)}²⁻

HHPO_{4(aq)}²⁻→H_{(aq)}⁺+PO_{4(aq)}³⁻

The above-described high Kₐ₁ acids may be included in a range of concentrations. For example, a high Kₐ₁ acid: HF ratio may be in a range from approximately 1:100 to approximately 100:1, such as 1:50 to 50:1, including 1:20 to 20:1, such as 1:10 to 10:1, for example.

Various etch byproducts including Ba and Sr may be formed in solution and may be carried away by the aqueous medium. Further, the solubility of etch products (such as Ba or Sr salts) may be tuned (e.g., enhanced) by appropriate changes in a pH of the solution. As an example, the barium fluoride etch byproduct of BTO may partially dissociate in the etch bath according to reaction (V) as follows:

BaF₂₍ₛ₎↔Ba_{(aq)}²⁺+2F_{(aq)}⁻ (V)

When the high Kₐ₁ acid is added to the etching medium, it will generate hydronium ions which react with the fluorine ions generated in reaction (V) according to reaction (II). When the fluorine ions in reaction (V) are consumed, the equilibrium of this reaction is pushed forward according to Le Chatelier's principle. In other words, the solubility of BaF₂ (an exemplary etch product residue) may be enhanced and BaF₂ may be more easily removed from the surface of the etched BTO.

In one embodiment, the wet etching method is used to etch single crystal or highly epitaxial BTO and/or STO, for which conventional wet etching methods may not be suitable. In this regard, conventional wet etching methods used to etch polycrystalline or nanocrystalline BTO or STO rely on the presence of defects, grain boundaries, and higher porosity microstructures typical of polycrystalline or nanocrystalline materials to achieve practical etch rates. Such defects, grain boundaries, etc., do not exist or exist in very low quantities in high quality single crystal or highly epitaxial materials. Thus, the disclosed wet etching methods that include catalyzed etching reactions may be used to etch single crystal or highly epitaxial materials.

Disclosed embodiments may also be useful for etching metal oxide materials (e.g., BTO or STO) formed on silicon substrates. In this regard, the above-described wet etching medium, when used in a dilute solution, rapidly etches thin film BTO and STO materials but does not appreciably etch silicon, making it possible to use the disclosed etching methods in applications that include metal oxide materials to be etched formed on silicon substrates.

The above-described etching method may be used in many applications including photonics (e.g., devices with electro-optic materials, oxide perovskite materials, optical switches, interferometers, etc.); microelectromechanical systems (MEMS) (e.g., disclosed embodiments may be used in thermal detectors to etch pixels in a focal plane arrays (FPA) and bolometers); communications systems (e.g., disclosed embodiments may be used to pattern reflectarray antennas); memory devices (e.g., disclosed embodiments may be used to pattern thin film capacitors and varactors); etc.

The foregoing descriptions are provided merely as illustrative examples and are not intended to require or imply that the steps of the various embodiments must be performed in the order presented. As may be appreciated by one of ordinary skill in the art, the order of steps in the foregoing embodiments may be performed in any order. Words such as “thereafter,” “then,” “next,” etc., are not necessarily intended to limit the order of the steps; these words may be used to guide the reader through the description of the methods. Further, any reference to claim elements in the singular, for example, using the articles “a,” “an,” or “the,” is not to be construed as limiting the element to the singular. Further, any step or component of any embodiment described herein may be used in any other embodiment.

The preceding description of the disclosed aspects is provided to enable persons of ordinary skill in the art to make and/or use the disclosed embodiments. Various modifications to these aspects may be readily apparent to those of ordinary skill in the art, and the generic principles defined herein may be applied to other aspects without departing from the scope of the disclosure. Thus, embodiments of the disclosure are not intended to be limited to the aspects shown herein but is to be accorded the widest scope consistent with the principles and novel features disclosed herein.

What is claimed is:

1. An etching method, comprising:
forming a metal oxide layer comprising a barium titanate layer or a strontium titanate layer over a substrate;
forming a patterned masking layer over the metal oxide layer; and
etching the metal oxide layer using a wet etching medium comprising hydrofluoric acid, one or more additional acids having an acid dissociation constant greater than that of the hydrofluoric acid, and a diluent.

2. The method of claim 1, wherein the wet etching medium further comprises one or more of an oxidizing agent, a surfactant, or a solvent.

3. The method of claim 1, wherein the wet etching medium further comprises an oxidizing agent comprising hydrogen peroxide.

4. The method of claim 1, wherein the wet etching medium further comprises a solvent comprising ethanol.

5. The method of claim 1, wherein the one or more additional acids comprise one or more of hydroiodic acid, perchloric acid, hydrobromic acid, hydrochloric acid, sulfuric acid, nitric acid, phosphoric acid, citric acid, oxalic acid, or acetic acid.

6. The method of claim 1, wherein the wet etching medium comprises an additional acid: HF ratio that is in a range from approximately 1:100 to approximately 100:1.

7. The method of claim 1, wherein the step of etching the metal oxide layer is an isotropic wet etching process which forms undercut etched regions in the metal oxide layer under portions of the patterned masking layer.

8. The method of claim 1, wherein the wet etching medium comprises an aqueous solution which dissolves barium or strontium containing etching residue.

9. The method of claim 1, wherein the patterned masking layer comprises a photoresist.

10. The method of claim 1, wherein the step of etching the metal oxide layer forms a patterned metal oxide layer which contains a ridge portion having tapered sidewalls and horizontal layer portions located on each side of the ridge portion over the substrate.

11. The method of claim 10, wherein the patterned metal oxide layer comprises a waveguide layer of a Mach-Zehnder interferometer.

12. The method of claim 10, wherein the metal oxide layer comprises the barium titanate layer.

13. The method of claim 12, further comprising forming a first electrode and a second electrode on the horizontal layer portions.

14. The method of claim 10, wherein the metal oxide layer comprises the strontium titanate layer.

15. The method of claim 1, wherein forming the metal oxide layer comprises forming the strontium titanate layer over the substrate and forming the barium titanate layer over the strontium titanate layer.

16. The method of claim 15, wherein the patterned metal oxide layer comprises a barium titanate ridge portion having tapered sidewalls located over the strontium titanate layer.

17. The method of claim 16, wherein the barium titanate ridge portion comprises a waveguide layer of a Mach-Zehnder interferometer.

18. The method of claim 1, wherein the step of etching the metal oxide layer comprises placing the substrate containing the metal oxide layer and the patterned masking layer into a bath comprising the wet etching medium.

19. The method of claim 1, wherein the step of etching the metal oxide layer comprises spraying the wet etch medium on exposed portions of the metal oxide layer and on the patterned masking layer.

20. The method of claim 1, wherein the step of etching the metal oxide layer comprises providing a vapor from the wet etching medium onto exposed portions of the metal oxide layer and on the patterned masking layer.
